(19) United States
(12) Patent Application Publication
(10) Pub. No.: US 2026/0209927 A1
(43) Pub. Date: Jul. 23, 2026

(54) DEPOSITION MASK, METHOD OF MANUFACTURING THE DEPOSITION MASK, AND APPARATUS FOR MANUFACTURING DISPLAY PANEL

(71) Applicant: Samsung Display Co., LTD., Yongin-si (KR)

(72) Inventor: Sungwoon KIM, Yongin-si (KR)

(21) Appl. No.: 19/315,045

(22) Filed: Aug. 29, 2025

(30) Foreign Application Priority Data
Jan. 21, 2025 (KR) 10-2025-0008852

(51) Int. Cl. C23C 14/04

(52) U.S. Cl. CPC C23C 14/042

(57) ABSTRACT

A deposition mask includes a mask frame including a first surface and a second surface opposite to the first surface, wherein a first opening is defined in the mask frame to be open toward the first surface, and a second opening is defined in the mask frame to be open toward the second surface; and a mask membrane of which at least a portion is arranged in the first opening of the mask frame, the mask membrane including a protrusion protruding beyond an inner edge of the mask frame defining the second opening and protruding inside.

This application claims priority to Korean Patent Application No. 10-2025-0008852, filed on Jan. 21, 2025, and all the benefits accruing therefrom under 35 U.S.C. § 119, the content of which in its entirety is herein incorporated by reference.

### BACKGROUND

### 1. Field

One or more embodiments relate to a deposition mask. One or more embodiments relate to a method of manufacturing the deposition mask. One or more embodiments relate to an apparatus for manufacturing a display panel, and more particularly, to a manufacturing apparatus including the deposition mask.

### 2. Description of the Related Art

Various types of electronic apparatuses include display panels to visually display data thereon. The display panels may provide images by using light-emitting diodes. The display panels have become more diverse in their uses and structures, and structures that may be bent to a certain angle from a flat state have also been developed. Recently, various attempts have been made to design display panels with improved quality.

A display panel may include a plurality of pixels in the form of a pattern to implement images. In this case, a plurality of layers including an emission layer may be included in the plurality of pixels in the form of a pattern. These layers may be arranged on a substrate in different patterns based on their types.

### SUMMARY

Each layer of a display panel may be formed by depositing a deposition material by using a deposition mask including a deposition opening corresponding to a pattern to be formed on a substrate. The deposition mask may include a mask membrane in which a deposition opening corresponding to the pattern is defined, and a mask frame to which the mask membrane is fixed. During a process of manufacturing the deposition mask, the mask membrane may be damaged by an impact applied to the mask membrane due to, for example, a sharp end of the mask frame. A structure for preventing damage to the mask membrane is required.

Additional aspects will be set forth in part in the description which follows and, in part, will be apparent from the description, or may be learned by practice of the presented embodiments of the disclosure.

According to one or more embodiments, a deposition mask includes a mask frame including a first surface and a second surface opposite to the first surface, wherein a first opening is defined in the mask frame to be open toward the first surface, and a second opening is defined in the mask frame to be open toward the second surface; and a mask membrane of which at least a portion is arranged in the first opening of the mask frame, the mask membrane including a protrusion protruding beyond an inner edge of the mask frame defining the second opening and protruding inside.

In an embodiment, a size of the first opening may be greater than or equal to a size of the second opening.

In an embodiment, the first opening and the second opening may communicate to each other and penetrate the mask frame together.

In an embodiment, an inner side of the mask frame defining the second opening may be tapered such that a size of the second opening changes in a direction toward the first opening.

In an embodiment, the protrusion may have a round edge.

In an embodiment, a portion of the mask membrane may protrude beyond the first surface of the mask frame and protrude upward.

In an embodiment, the mask membrane may include a third opening defined by the protrusion and overlapping the first opening and the second opening of the mask frame in a plan view, and a plurality of fourth openings overlapping the first opening, the second opening, and the third opening, the plurality of fourth openings defining a deposition area.

In an embodiment, a portion of the mask membrane defining the third opening therein may be arranged in the first opening, and another portion of the mask membrane defining the plurality of fourth openings therein may be arranged above and protrude from the first surface of the mask frame.

According to one or more embodiments, a method of manufacturing a deposition mask includes forming a trench in a first surface of a mask frame substrate, arranging a mask membrane on the first surface of the mask frame substrate to fill the trench of the mask frame substrate, and etching the mask frame substrate from a second surface thereof such that a portion of the mask membrane arranged in the trench is exposed, the second surface being opposite to the first surface.

In an embodiment, the method may further include before the arranging of the mask membrane, arranging a temporary layer on an outer surface of the mask frame substrate to cover the first surface and the second surface of the mask frame substrate.

In an embodiment, the method may further include forming a first temporary opening in a first portion of the temporary layer arranged on the first surface of the mask frame substrate, the first temporary opening overlapping the trench of the mask frame substrate in a plan view.

In an embodiment, during the arranging of the temporary layer, the trench of the mask frame substrate may be filled with the first portion of the temporary layer, and during the forming of the first temporary opening, a portion of the temporary layer arranged in the trench may be removed.

In an embodiment, the arranging of the temporary layer may be performed prior to the forming of the trench of the mask frame substrate, and the forming of the first temporary opening of the temporary layer may be performed simultaneously with or prior to the forming of the trench of the mask frame substrate.

In an embodiment, the trench of the mask frame substrate and the first temporary opening of the temporary layer may each be formed as a closed-loop in the plan view, and the method may further include forming a plurality of second temporary openings in the first portion of the temporary layer, the plurality of second temporary openings being arranged in the closed-loop in the plan view.

In an embodiment, the method may further include removing a portion of the mask membrane protruding outside the first temporary opening or outside the plurality of second temporary openings.

In an embodiment, the method may further include removing the temporary layer.

In an embodiment, in the etching of the mask frame substrate from the second surface, the etching may be performed to penetrate the mask frame substrate from the second surface to the first surface.

In an embodiment, a portion of the mask membrane arranged in the trench and exposed by the etching of the mask frame substrate may protrude beyond an inner edge of the mask frame defining an opening formed by the etching of the mask frame substrate.

According to one or more embodiment, an apparatus for manufacturing a display panel includes a chamber, a deposition mask arranged in the chamber, and a deposition source arranged to face the deposition mask in the chamber, where the deposition mask includes a mask frame including a first surface and a second surface opposite to the first surface, wherein a first opening is defined in the mask frame to be open toward the first surface, and a second opening is defined in the mask frame to be open toward the second surface, and a mask membrane of which at least a portion is arranged in the second opening of the mask frame, the mask membrane including a protrusion protruding beyond an inner edge of the mask frame defining the first opening and protruding inside.

### BRIEF DESCRIPTION OF THE DRAWINGS

The above and other aspects, features, and advantages of certain embodiments

of the disclosure will be more apparent from the following description taken in conjunction with the accompanying drawings, in which:

FIGS. 1A and 1B are cross-sectional views of an apparatus for manufacturing a display panel according to an embodiment;

FIG. 2 is a plan view of a mask frame according to an embodiment;

FIG. 3 is a cross-sectional view of a mask frame according to an embodiment;

FIG. 4 is a plan view of a deposition mask according to an embodiment;

FIG. 5 is a cross-sectional view of a deposition mask according to an embodiment;

FIG. 6 is a cross-sectional view of a deposition mask according to an embodiment;

FIG. 7 is a cross-sectional view of a deposition mask according to an embodiment;

FIGS. 8A, 8B, 8C, 8D, 8E, 8G, 8H, 8I, and 8J are schematic cross-sectional views illustrating processes of a method of manufacturing a deposition mask, according to an embodiment;

FIG. 8F is a schematic plan view illustrating a process of a method of manufacturing a deposition mask, according to an embodiment;

FIGS. 9A, 9B, 9C, and 9D are schematic cross-sectional views illustrating processes of a method of manufacturing a deposition mask, according to an embodiment;

FIG. 10 is a block diagram of an electronic apparatus according to an embodiment;

FIGS. 11, 12, and 13 are schematic diagrams of an electronic apparatus according to various embodiments;

FIG. 14 is a schematic plan view of an electronic apparatus according to an embodiment; and

FIG. 15 is a cross-sectional view of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because various modifications may be applied and one or more embodiments may be implemented, specific embodiments will be shown in the drawings and described in detail in the detailed description. Effects and features, and methods for achieving them will be clarified with reference to embodiments described below in detail with reference to the drawings. However, the embodiments may have different forms and should not be construed as being limited to the descriptions set forth herein.

Hereinafter, the embodiments will now be described in detail with reference to the accompanying drawings. When described with reference to the drawings, identical or corresponding elements will be given the same reference numerals, and redundant description of these elements will be omitted.

It will be understood that although terms “first” and “second” may be used herein to describe various elements, these elements should not be limited by these terms and these terms are only used to distinguish one element from another.

In the following embodiments, the singular forms include the plural forms unless the context clearly indicates otherwise.

It will be understood that terms “comprise,” “include,” and “have” used herein specify the presence of stated features or elements, but do not preclude the presence or addition of one or more other features or elements.

It will be further understood that, when a layer, region, or element is referred to as being “on”, “over”, “below”, or “at the bottom of” another layer, region, or element, it can be directly or indirectly on or below the other layer, region, or element. That is, for example, intervening layers, regions, or elements may be present.

Sizes of elements in the drawings may be exaggerated or reduced for convenience of description. For example, because sizes and thicknesses of elements in the drawings are arbitrarily illustrated for convenience of explanation, the embodiments are not limited thereto.

In the following embodiments, a first direction DR1, a second direction DR2, and a third direction DR3 are not limited to three directions of the rectangular coordinate system and may be interpreted in a broader sense. For example, the first direction DR1, the second direction DR2, and the third direction DR3 may be orthogonal to each other, but may also refer to different directions that are not orthogonal to each other.

When a certain embodiment may be implemented differently, a specific process order may also be performed differently from the described order. As an example, two processes that are successively described may be performed substantially simultaneously or performed in an order opposite to the order described.

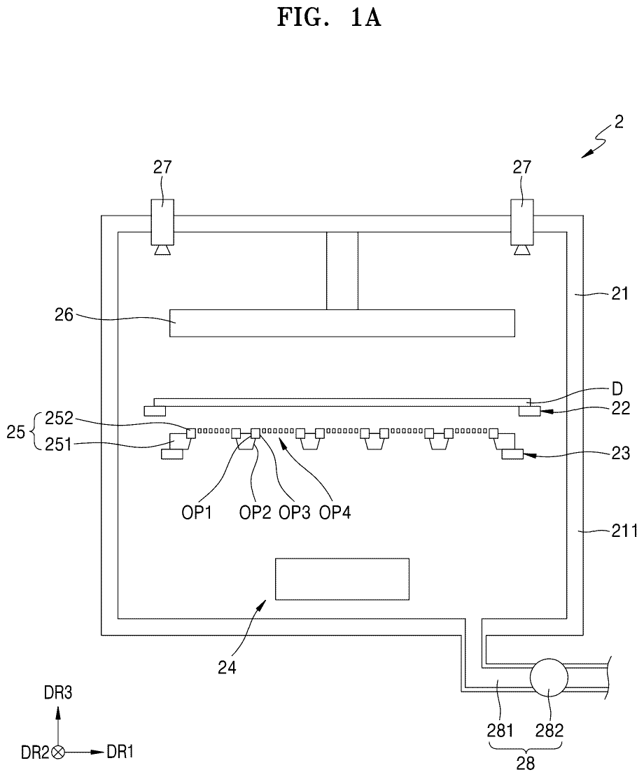

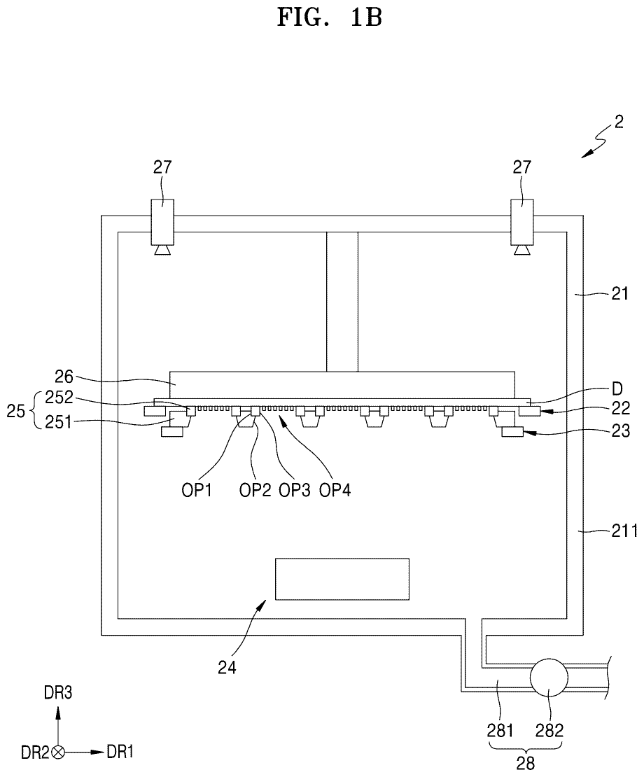

FIGS. 1A and 1B are cross-sectional views of an apparatus 2 for manufacturing a display panel according to an embodiment.

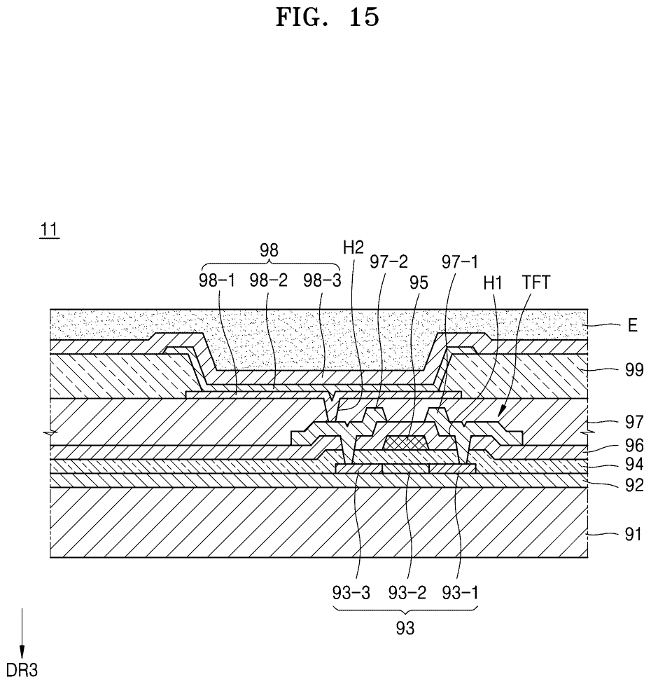

Referring to FIGS. 1A and 1B, the apparatus 2 for manufacturing a display panel may include a chamber 21, a first support 22, a second support 23, a deposition source 24, a deposition mask 25, a magnetic force portion 26, a vision portion 27, and a pressure controller 28. In an embodiment, the apparatus 2 may include a deposition apparatus. FIG. 1A illustrates an embodiment in which the deposition mask 25, an object D to be treated, and the magnetic force portion 26 are spaced apart from each other. FIG. 1B illustrates an embodiment in which the deposition mask 25, the object D to be treated, and the magnetic force portion 26 are in close contact with each other. In the present specification, the object D to be treated is a treatment target of the apparatus 2 and may include a semi-finished product of a display panel 11 (see FIG. 15). For example, the object D to be treated may include a semi-finished product formed up to an arbitrary layer among layers included in the display panel 11 (see FIG. 15). Some of the components of the apparatus 2 illustrated in FIGS. 1A and 1B may be omitted, and the apparatus 2 may further include components other than the components illustrated in FIGS. 1A and 1B.

The chamber 21 may have an inner space formed therein and may have an open portion. A gate valve 211 may be installed in the open portion of the chamber 21. In this case, the open portion of the chamber 21 may be opened or closed according to the operation of the gate valve 211.

The first support 22 may have the object D to be treated mounted thereon and support the same. In an embodiment, the first support 22 may be in the form of a frame fixed inside the chamber 21. In an embodiment, the first support 22 may be in the form of a shuttle on which the object D to be treated is mounted and which is linearly movable inside the chamber 21. In an embodiment, the first support 22 may include an electrostatic chuck or an adhesive chuck that is fixed to the chamber 21 or arranged in the chamber 21 to be elevated or lowered inside the chamber 21. Hereinafter, for convenience of description, a case where the first support 22 is in the form of a frame fixed inside the chamber 21 is mainly described in detail.

The deposition mask 25 may be mounted on the second support 23. In an embodiment, the second support 23 may be arranged inside the chamber 21. The second support 23 may finely adjust the position of the deposition mask 25. In an embodiment, the second support 23 may include a separate driver or align unit to enable the deposition mask 25 to move in different directions. In an embodiment, the second support 23 may be in the form of a shuttle. In an embodiment, the second support 23 may have the deposition mask 25 mounted thereon and may transfer the deposition mask 25. For example, the second support 23 may move outside the chamber 21, have the deposition mask 25 mounted thereon, and then enter the chamber 21 from outside the chamber 21.

The first support 22 and the second support 23 may be integrally formed as a single body. In this case, the first support 22 and the second support 23 may include a movable shuttle. In this case, the first support 22 and the second support 23 may include a structure for fixing the deposition mask 25 and the object D to be treated in a state in which the object D to be treated is mounted on the deposition mask 25, and may cause the object D to be treated and the deposition mask 25 to linearly move simultaneously.

Hereinafter, for convenience of description, an embodiment in which the first support 22 and the second support 23 are formed to be distinguished from each other and are arranged at different directions in the chamber 21 is mainly described in detail.

The deposition source 24 may be arranged to face the deposition mask 25. In an embodiment, a deposition material may be stored in the deposition source 24, and the deposition material may be evaporated or sublimated by applying heat to the deposition material. The deposition source 24 may be arranged to be fixed inside the chamber 21 or may be arranged inside the chamber 21 to be linearly movable in one direction. Hereinafter, for convenience of description, a case where the deposition source 24 is fixed inside the chamber 21 is mainly described in detail.

The deposition mask 25 may include a mask frame 251 and a mask membrane 252. A first opening OP1 and a second opening OP2 may be defined in the mask frame 251. The mask membrane 252 may be arranged in the first opening OP1 of the mask frame 251. A third opening OP3 and a fourth opening OP4 may be defined in the mask membrane 252. The third opening OP3 of the mask membrane 252 may overlap the first opening OP1 of the mask frame 251 in a plan view. A plurality of fourth openings OP4 may be provided in the mask membrane 252 and may define a deposition area of the deposition mask 25. The deposition area may refer to an area (or pattern) where a deposition material sprayed from the deposition source 24 is arranged on the object D to be treated.

The magnetic force portion 26 may be arranged in the chamber 21 to face the object D to be treated. In an embodiment, the magnetic force portion 26 may pull the deposition mask 25 toward the object D to be treated by applying a magnetic force (e.g., an attractive force) to the deposition mask 25 (e.g., the mask membrane 252). The magnetic force portion 26 may not only prevent the mask membrane 252 from sagging, but may also bring the mask membrane 252 into close contact with the object D to be treated. The magnetic force portion 26 may uniformly maintain a gap between the mask membrane 252 and the object D to be treated in a longitudinal direction (e.g., the first direction DR1 or the second direction DR2) of the mask membrane 252.

The vision portion 27 may be installed in the chamber 21 and capture images of the positions of the object D to be treated and the deposition mask 25. In an embodiment, the vision portion 27 may include a camera that captures images of the object D to be treated and the deposition mask 25. The positions of the object D to be treated and the deposition mask 25 may be identified based on the images captured by the vision portion 27, and based on the images, the position of the object D to be treated on the first support 22 may be finely adjusted, or the position of the deposition mask 25 on the second support 23 may be finely adjusted.

The pressure controller 28 may be connected to the chamber 21 and adjust the internal pressure of the chamber 21. For example, the pressure controller 28 may adjust the internal pressure of the chamber 21 to be equal to or similar to the atmospheric pressure. Also, the pressure controller 28 may adjust the internal pressure of the chamber 21 to be equal to or similar to the atmospheric pressure.

The pressure controller 28 may include a connection pipe 281 connected to the chamber 21 and a pump 282 installed in the connection pipe 281. In this case, according to the operation of the pump 282, outside air may be introduced through the connection pipe 281, or gas inside the chamber 21 may be guided to the outside through the connection pipe 281.

In an embodiment, the apparatus 2 may be used to manufacture a display panel by operating through a process described below. First, when the pressure controller 28 adjusts the inside of the chamber 21 to a state equal to or similar to the atmospheric pressure, the gate valve 211 may operate to open the open portion of the chamber 21.

Thereafter, the object D to be treated may be loaded from the outside into the chamber 21. In this case, the object D to be treated may be loaded into the chamber 21 by using various methods. In an embodiment, the object D to be treated may be loaded into the chamber 21 from outside the chamber 21 by means of a robot arm arranged outside the chamber 21. In an embodiment, when the first support 22 is formed as a shuttle, after the first support 22 is moved from inside the chamber 21 to outside the chamber 21, the object D to be treated may be mounted on the first support 22 through a separate robot arm arranged outside the chamber 21, and the first support 22 may be loaded into the chamber 21 from outside the chamber 21. Hereinafter, for convenience of description, a case where the object D to be treated is loaded into the chamber 21 from outside the chamber 21 through the robot arm arranged outside the chamber 21 is mainly described in detail.

The deposition mask 25 may be arranged inside the chamber 21 as described above. In an embodiment, the deposition mask 25 may also be loaded into the chamber 21 from outside the chamber 21 in the same or similar manner as the object D to be treated. In an embodiment, the first support 22 and the second support 23 may be in the form of a shuttle, and the object D to be treated and the deposition mask 25 may be fixed to the shuttle and loaded into the chamber 21 from outside the chamber 21. Hereinafter, for convenience of description, a case where only the object D to be treated is loaded into the chamber 21 from outside the chamber 21 in a state in which the deposition mask 25 is arranged inside the chamber 21 is mainly described in detail.

When the object D to be treated is loaded into the chamber 21, the object D to be treated may be mounted on the first support 22. The vision portion 27 may capture images of the positions of the object D to be treated and the deposition mask 25. In an embodiment, the vision portion 27 may capture a first align mark of the object D to be treated and a second align mark of the deposition mask 25.

The positions of the object D to be treated and the deposition mask 25 may be identified based on the captured first align mark and the second align mark. In an embodiment, the apparatus 2 includes a separate controller and thus may identify the positions of the object D to be treated and the deposition mask 25. When the positions of the object D to be treated and the deposition mask 25 are identified, the second support 23 may finely adjust the position of the deposition mask 25. Alternatively, the first support 22 may finely adjust the position of the object D to be treated. Accordingly, the object D to be treated and the deposition mask 25 may be aligned.

After the object D to be treated and the deposition mask 25 are aligned, the object D to be treated and the deposition mask 25 may be brought into close contact with each other. In an embodiment, the object D to be treated, the deposition mask 25, and the magnetic force portion 26 may be brought into proximity with each other. In an embodiment, as shown in FIGS. 1A and 1B, the object D to be treated may not move, and the deposition mask 25 may move toward the object D to be treated (e.g., in the third direction DR3) and the magnetic force portion 26 may move toward the object D to be treated (e.g., in a direction opposite to the third direction DR3). In an embodiment, the deposition mask 25 may not move, and the object D to be treated and the magnetic force portion 26 may move toward the deposition mask 25 (e.g., in the direction opposite to the third direction DR3). In an embodiment, the magnetic force portion 26 may pull the deposition mask 25 toward the object D to be treated (e.g., in the third direction DR3) by applying a magnetic force (e.g., an attractive force) to the deposition mask 25. In an embodiment, the deposition mask 25, for example, the mask membrane 252, may be in close contact with the object D to be treated. For example, the mask membrane 252 may be in close contact with a surface of the deposition mask 25 facing the direction opposite to the third direction DR3.

Thereafter, a deposition source 244 may operate to spray a deposition material toward the deposition mask 25 (e.g., in the third direction DR3). The deposition material passing through the plurality of fourth openings OP4 of the mask membrane 252 may be deposited on the object D to be treated. In this case, the pump 282 may maintain the internal pressure of the chamber 21 in a vacuum-like or similar state by sucking in the gas inside the chamber 21 and discharging the gas to the outside. The deposition material passing through the fourth openings OP4 of the mask membrane 252 and deposited on the object D to be treated may have substantially the same shape (pattern) as those of the fourth openings OP4. The fourth openings OP4 of the mask membrane 252 are formed to correspond to a designed deposition area and may provide a deposition area that is identical to or similar to the designed deposition area.

The above process may be repeatedly performed on a plurality of objects D to be treated. In this case, when the number of depositions for the plurality of objects D to be treated becomes equal to a preset number of times, the operation of the apparatus 2 may be stopped, and the deposition mask 25 may be withdrawn to the outside of the chamber 21. Thereafter, a new deposition mask 25 may be loaded into the chamber 21, and the above operation may be repeated.

Through the above process, the apparatus 2 may deposit the deposition material on the object D to be treated in an area identical to or similar to a designed pattern. Also, because the apparatus 2 may deposit the deposition material in a precise pattern, a display panel capable of implementing precise images may be manufactured.

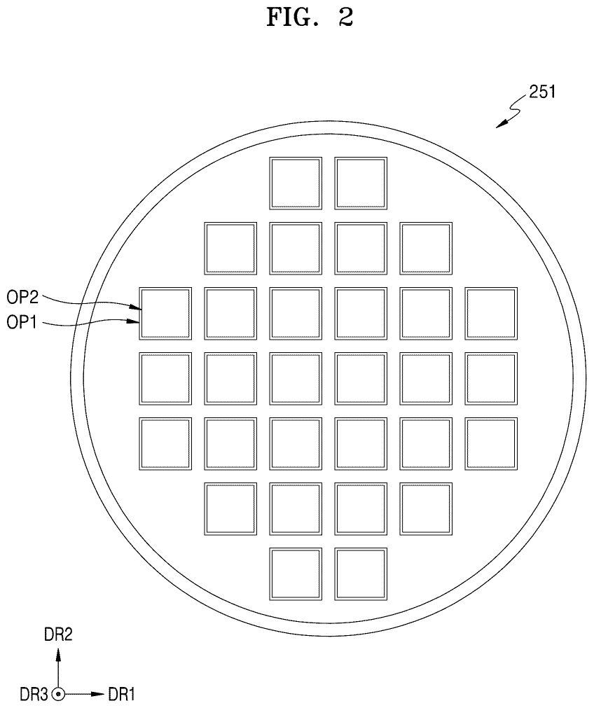

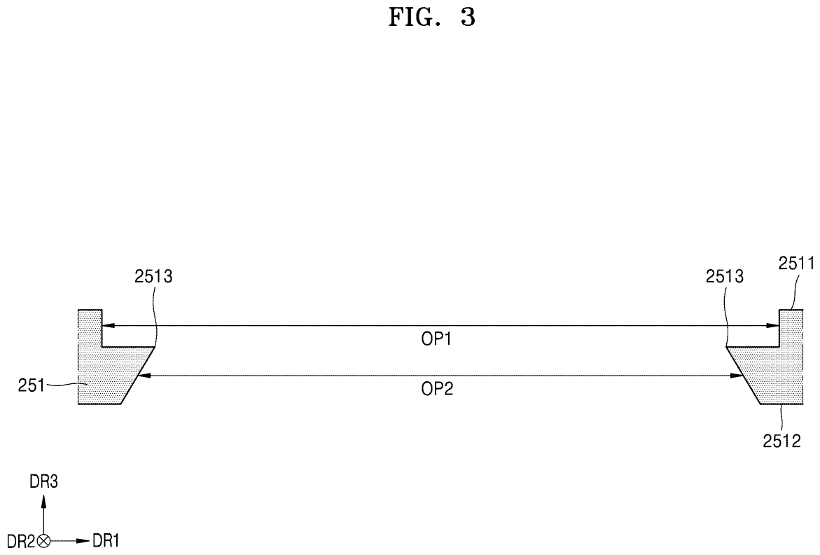

FIG. 2 is a plan view of the mask frame 251 according to an embodiment. FIG. 3 is a cross-sectional view of a region of the mask frame 251 according to an embodiment. As used herein, the plan view is a view in a thickness direction (i.e., third direction DR3) of the mask frame.

Referring to FIGS. 2 and 3, the first opening OP1 and the second opening OP2 may be defined in the mask frame 251. In an embodiment, a plurality of first openings OP1 and a plurality of second openings OP2 may be defined in the mask frame 251. The plurality of first openings OP1 may be arranged to be spaced apart from each other. The plurality of first openings OP1 may be arranged side by side in one direction. For example, the first openings OP1 may be arranged side by side in the first direction DR1 and/or the second direction DR2. In an embodiment, the mask frame 251 may include silicon (Si). In an embodiment, the mask frame 251 may be provided in the form of a silicon wafer.

FIG. 2 illustrates an embodiment in which the mask frame 251 has a substantially circular shape, but one or more embodiments are not limited thereto. The mask frame 251 may have various shapes, such as polygonal, elliptical, and irregular shapes. FIG. 2 illustrates an embodiment in which the plurality of first openings OP1 have a substantially square shape, but one or more embodiments are not limited thereto. The plurality of first openings OP1 may have various shapes, such as polygonal, elliptical, and irregular shapes, and the shapes and/or sizes of the plurality of first openings OP1 may be different from each other. FIG. 2 illustrates an embodiment in which the plurality of second openings OP2 have a substantially square shape, but one or more embodiments are not limited thereto. The plurality of second openings OP2 may have various shapes, such as polygonal, elliptical, and irregular shapes, and the shapes and/or sizes of the plurality of second openings OP2 may be different from each other.

FIG. 3 illustrates one first opening OP1 and one second opening OP2 among the plurality of first openings OP1 and the plurality of second openings OP2 provided in the mask frame 251. The mask frame 251 may include a first surface 2511 facing the third direction DR3, and a second surface 2512 facing the direction opposite to the third direction DR3. In an embodiment, the second surface 2512 may be opposite to the first surface 2511. In an embodiment, the first surface 2511 may be an upper surface (e.g., top surface) of the mask frame 251, and the second surface 2512 may be a lower surface (e.g., bottom surface) of the mask frame 251.

The first opening OP1 may be open toward the first surface 2511 of the mask frame 251. The second opening OP2 may be open toward the second surface 2512 of the mask frame 251. In an embodiment, the first opening OP1 and the second opening OP2 may be spatially connected to each other and may penetrate the mask frame 251 together (e.g., in the third direction DR3). In other words, the mask frame 251 may include an opening penetrating the mask frame 251, and a portion of the opening that is open toward the first surface 2511 of the mask frame 251 may be the first opening OP1, and a portion of the opening that is open toward the second surface 2512 may be the second opening OP2. In an embodiment, the sizes of the first opening OP1 and the second opening OP2 may be different from each other. In an embodiment, the size of the first opening OP1 may be equal to or greater than the size of the second opening OP2. In an embodiment, the size of the second opening OP2 may vary in one direction (e.g., the third direction DR3). In other words, the size of the second opening OP2 may change in one direction (e.g., the third direction DR3). In an embodiment, an inner side of the mask frame 251 that defines the second opening OP2 may be provided such that the size of the second opening OP2 changes in a direction (e.g., the third direction DR3) toward the first opening OP1. In an embodiment, an inner side of the mask frame 251 that defines the second opening OP2 may be tapered. As used herein, the size of the opening is measured in a plan view. A width of the first opening OP1 in a direction perpendicular to the third direction DR3 may be equal to or greater than a width of the second opening OP2 in the same direction. In an embodiment, the first opening OP1 may cover an entirety of the second opening OP2.

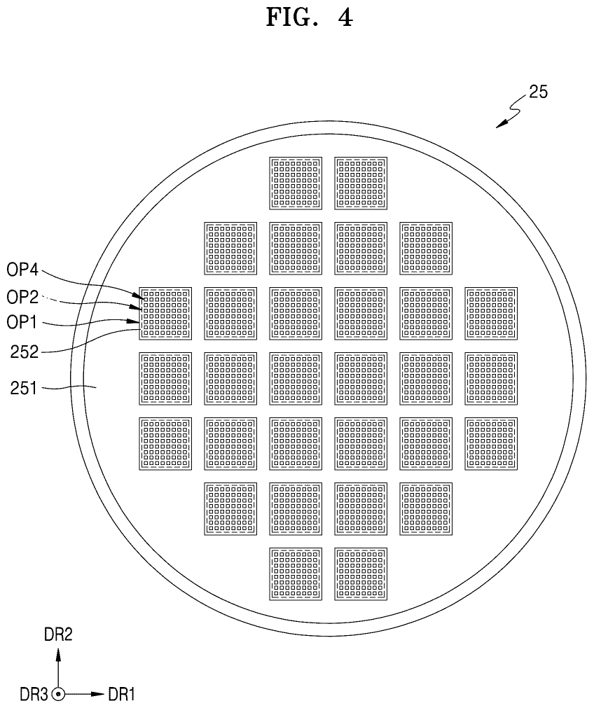

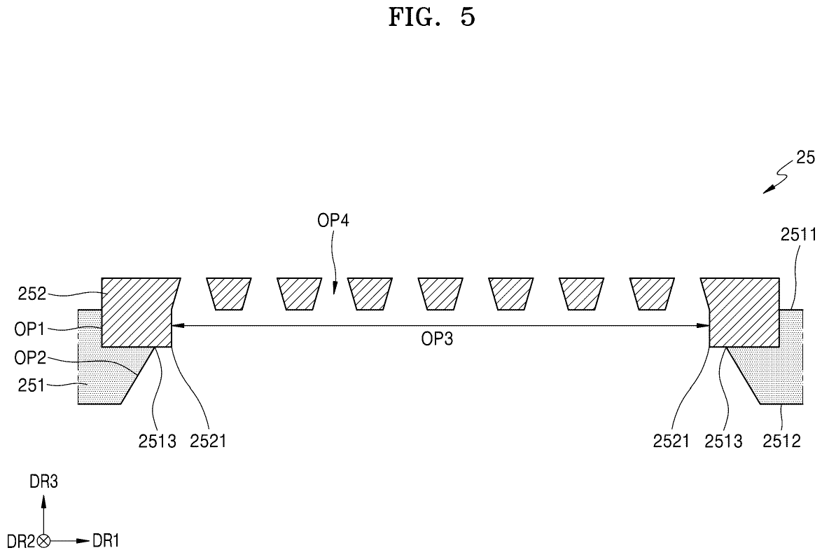

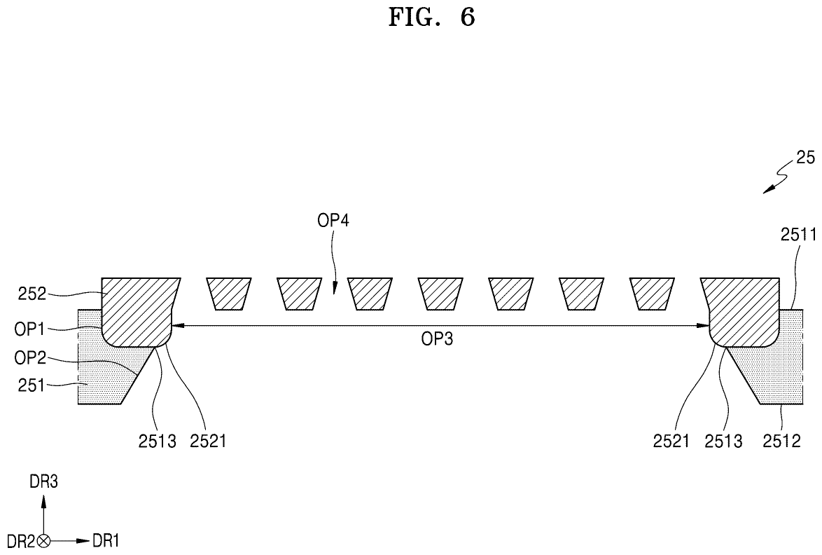

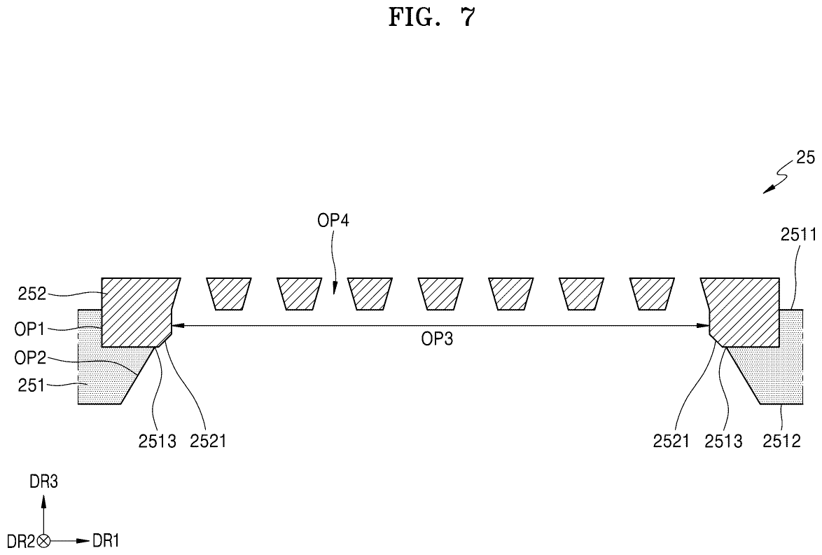

FIG. 4 is a plan view of the deposition mask 25 according to an embodiment. FIG. 5 is a cross-sectional view of a region of the deposition mask 25 according to an embodiment. FIG. 6 is a cross-sectional view of a region of the deposition mask 25 according to an embodiment. FIG. 7 is a cross-sectional view of a region of the deposition mask 25 according to an embodiment.

Referring to FIGS. 4 to 7, the deposition mask 25 may include the mask frame 251 and the mask membrane 252. The features of the mask frame 251 are the same as those described above with reference to FIGS. 2 and 3.

The mask membrane 252 may be arranged on the mask frame 251. In an embodiment, the mask membrane 252 may be arranged on one side of the mask frame 251 facing the third direction DR3. In an embodiment, the mask membrane 252 may include a metal. In an embodiment, the mask membrane 252 may include nickel (Ni). In an embodiment, the mask membrane 252 may include a nickel-iron alloy, for example, invar.

The third opening OP3 and the fourth opening OP4 may be defined in the mask membrane 252. In an embodiment, the mask membrane 252 may include a plurality of islands. One island of the mask membrane 252 may include one third opening OP3 and a plurality of fourth openings OP4. As shown in FIG. 4, one island of the mask membrane 252 may be arranged over the mask frame 251 to correspond to one first opening OP1 and one second opening OP2 of the mask frame 251.

In another embodiment, the mask membrane 252 may be provided as a single body and arranged over the mask frame 251. In this case, a plurality of third openings OP3 and a plurality of fourth openings OP4 of the mask membrane 252 may be provided to correspond to one first opening OP1, one second opening OP2, one third opening OP3, and a plurality of fourth openings OP4, respectively.

In the present specification, an embodiment in which the mask membrane 252 includes the plurality of islands is illustrated and described, and when one island is illustrated and described in a cross-sectional view, the island is referred to as the mask membrane 252 for convenience of description.

In an embodiment, one first opening OP1, one second opening OP2, one third opening OP3, and a plurality of fourth openings OP4 may correspond to each other. FIG. 4 illustrates an embodiment in which one first opening OP1, one second opening OP2, one third opening OP3, and sixty-four (64) fourth openings OP4 correspond to each other, but one or more embodiments are not limited to a specific number of fourth openings OP4.

FIG. 4 illustrates an embodiment in which the plurality of fourth openings OP4 have a substantially square shape, but one or more embodiments are not limited thereto. The plurality of fourth openings OP4 may have various shapes, such as polygonal, elliptical, and irregular shapes, and the shapes and/or sizes of the plurality of fourth openings OP4 may be different from each other. In an embodiment, the shapes of the plurality of fourth openings OP4 may be designed to implement a preset deposition pattern. In other words, the deposition area of the deposition mask 25 may be defined by the plurality of fourth openings OP4 of the mask membrane 252.

A portion of the mask membrane 252 may be arranged in the first opening OP1 of the mask frame 251. In an embodiment, a first portion of the mask membrane 252 that defines the third opening OP3 may be arranged in the first opening OP1 of the mask frame 251. Accordingly, the first opening OP1 of the mask frame 251 and the third opening OP3 of the mask membrane 252 may overlap each other (e.g., when seen in the first direction DR1 or the second direction DR2).

A portion of the mask membrane 252 may extend (or protrude) beyond the first surface 2511 of the mask frame 251. In an embodiment, a second portion of the mask membrane 252 that defines the plurality of fourth openings OP4 may extend (or protrude) beyond the first surface 2511 of the mask frame 251. In other words, the second portion of the mask membrane 252 may be arranged over the first surface 2511 of the mask frame 251 (e.g., in the third direction DR3 relative to the first surface 2511).

The size of the third opening OP3 of the mask membrane 252 may be smaller than the size of the second opening OP2 of the mask frame 251. In an embodiment, a portion of the mask membrane 252 that defines the third opening OP3 may protrude beyond an edge 2513 of the mask frame 251 that defines the second opening OP2. In other words, the mask membrane 252 may include a protrusion 2521 protruding beyond the edge 2513 of the mask frame 251 that defines the second opening OP2.

FIG. 5 illustrates an embodiment in which the edge of the protrusion 2521 is provided at a right angle. FIG. 6 illustrates an embodiment in which the edge of the protrusion 2521 is round. In an embodiment, as shown in FIG. 6, the edge of the mask membrane 252 in contact with the inner side of the mask frame 251 that defines the first opening OP1 may also be round. FIG. 7 illustrates an embodiment in which the edge of the protrusion 2521 is chamfered. In an embodiment, as shown in FIG. 7, the edge of the protrusion 2521 may have a chamfered shape, while the edge of the mask membrane 252 in contact with the inner side of the mask frame 251 that defines the first opening OP1 may be provided at a right angle. In an embodiment, the edge of the mask membrane 252 in contact with the inner side of the mask frame 251 that defines the first opening OP1 may also be chamfered.

The second portion of the mask membrane 252 that defines the plurality of fourth openings OP4 may have a relatively small thickness and/or low strength. Accordingly, when an impact, such as vibration, is applied to the deposition mask 25 in a state in which the edge 2513 of the mask frame 251 and the second portion of the mask membrane 252 are in direct contact with each other, the mask membrane 252 (e.g., the second portion) may be damaged by the edge 2513 of the mask frame 251. Because the mask membrane 252 has the protrusion 2521 and the first portion that defines the third opening OP3, the edge 2513 of the mask frame 251 may be separated from the second portion of the mask membrane 252, and the aforementioned damage may be prevented (or at least reduced).

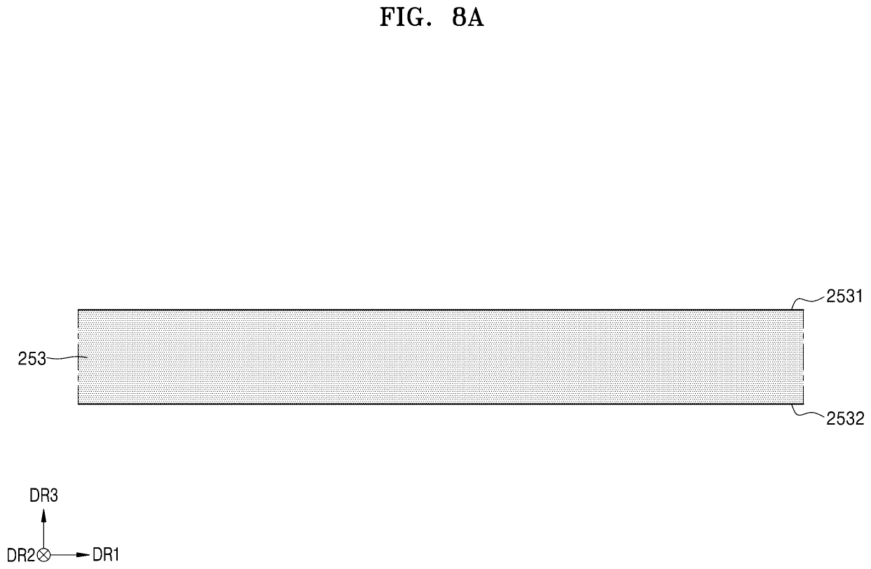

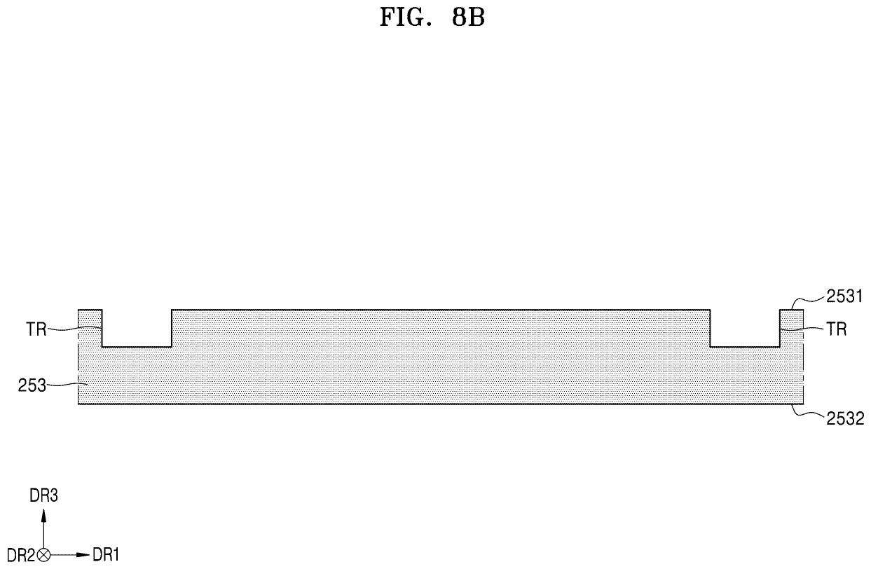

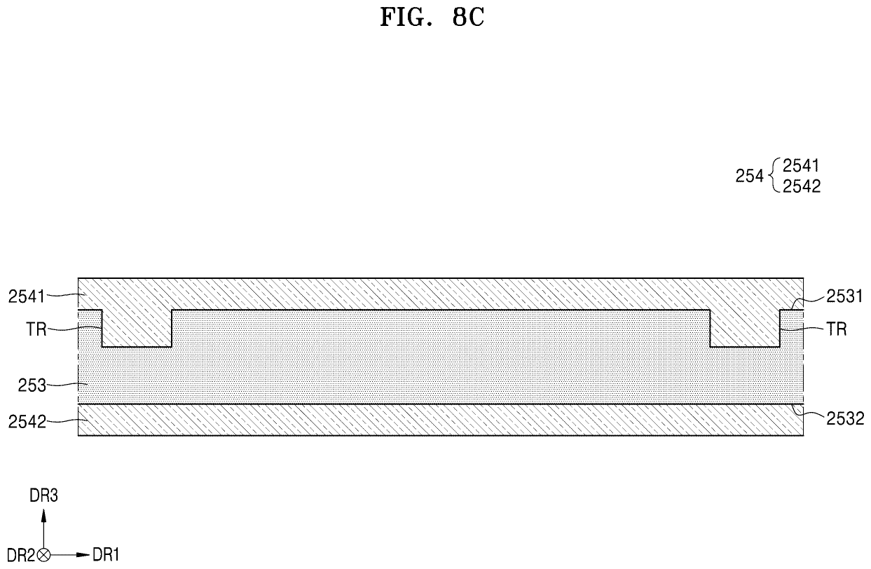

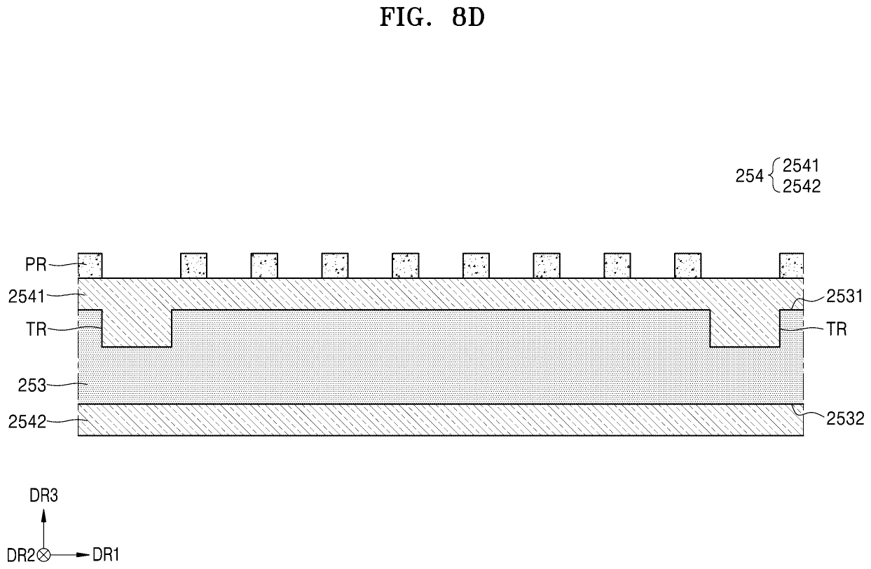

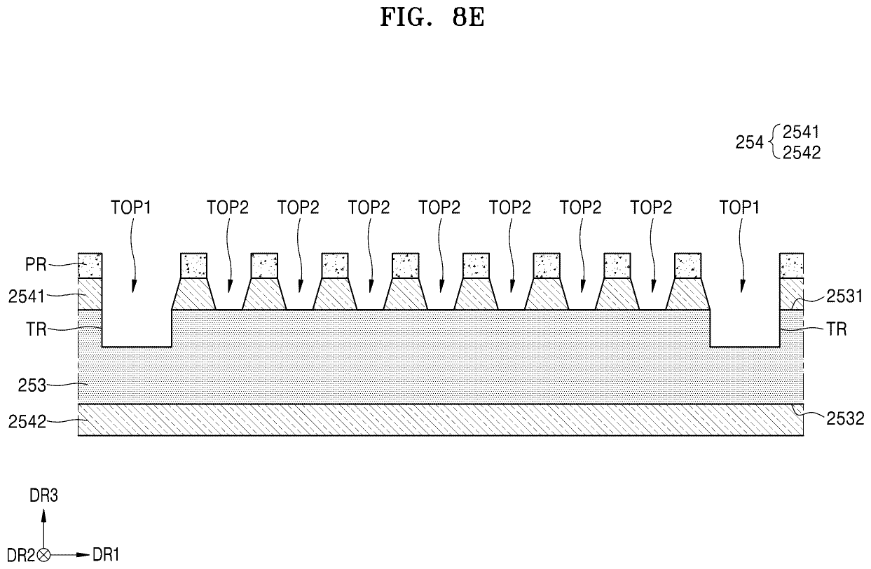

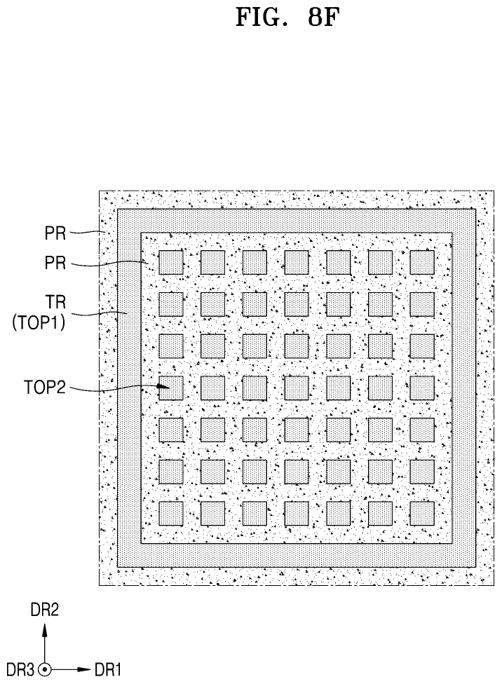

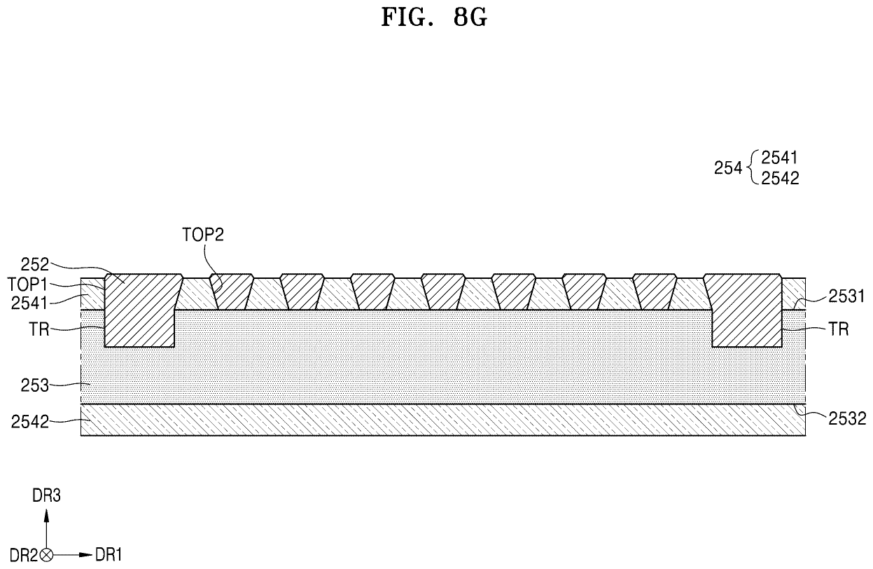

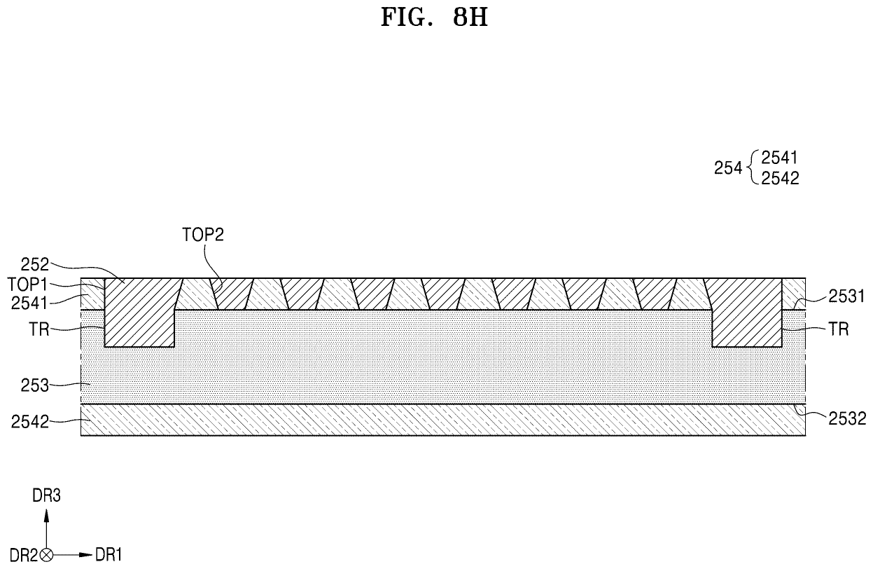

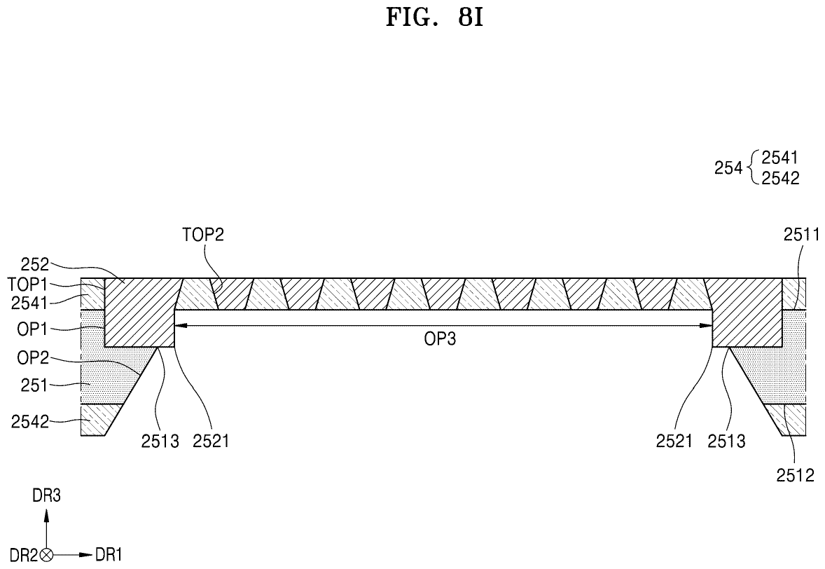

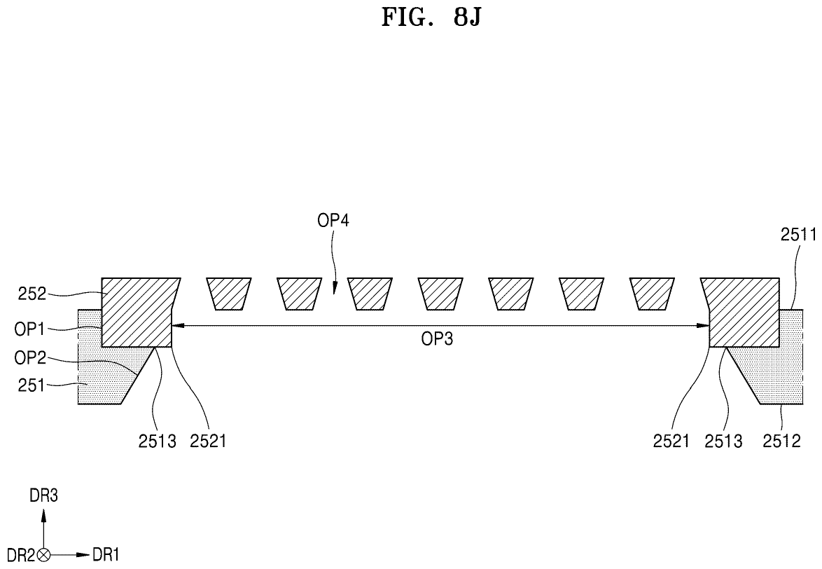

FIGS. 8A, 8B, 8C, 8D, 8E, 8G, 8H, 8I, and 8J are schematic cross-sectional views illustrating processes of a method of manufacturing a deposition mask, according to an embodiment. FIG. 8F is a schematic plan view illustrating a process of a method of manufacturing a deposition mask, according to an embodiment.

Referring to FIG. 8A, a mask frame substrate 253 may be prepared. The mask frame substrate 253 may include a first surface 2531 facing the third direction DR3, and a second surface 2532 facing a direction opposite to the third direction DR3. In an embodiment, the second surface 2532 may be opposite to the first surface 2531. In an embodiment, the first surface 2531 may be an upper surface (e.g., top surface) of the mask frame substrate 253, and the second surface 2532 may be a lower surface (e.g., bottom surface) of the mask frame substrate 253. In an embodiment, the mask frame substrate 253 may include Si. In an embodiment, the mask frame substrate 253 may be provided in the form of a silicon wafer.

Referring to FIG. 8B, a trench TR may be formed in the mask frame substrate 253. In an embodiment, the trench TR may be formed in the first surface 2531 of the mask frame substrate 253. In other words, the trench TR may be open toward the first surface 2531 of the mask frame substrate 253. In an embodiment, the trench TR may be formed as a closed-loop or frame shape in a plan view (see FIG. 8F). Accordingly, a trench TR arranged in the first direction DR1 and a trench TR arranged in a direction opposite to the first direction DR1, which are shown in FIG. 8B, may be spatially connected to each other.

Referring to FIG. 8C, a temporary layer 254 may be arranged on an outer surface of the mask frame substrate 253. A first portion 2541 of the temporary layer 254 may be arranged on the first surface 2531 of the mask frame substrate 253. A second portion 2542 of the temporary layer 254 may be arranged on the second surface 2532 of the mask frame substrate 253. In an embodiment, the trench TR of the mask frame substrate 253 may be filled by the first portion 2541 of the temporary layer 254. In an embodiment, the temporary layer 254 may include oxide, for example, silicon oxide (SiO₂). Although not shown, the first portion 2541 and the second portion 2542 of the temporary layer 254 may cover a side of the mask frame substrate 253 and be connected to each other.

Referring to FIG. 8D, a photoresist PR may be arranged on the temporary layer 254. In an embodiment, the photoresist PR may be arranged on the first portion 2541 of the temporary layer 254. The photoresist PR may be arranged in a form to implement a pattern to be described below. In an embodiment, the photoresist PR may include an opening overlapping the trench TR of the mask frame substrate 253 and may include a plurality of openings arranged in the trench TR (e.g., between two portions of the trench TR).

Referring to FIG. 8E, and 8F, the temporary layer 254 may be patterned. In an embodiment, patterning may include an etching process. In an embodiment, during the etching process, the temporary layer 254 may be exposed and then etched. In an embodiment, during the etching process, the temporary layer 254 may be etched by using the photoresist PR as a mask. In an embodiment, the first portion 2541 of the temporary layer 254 may be patterned (e.g., etched). In an embodiment, a first temporary opening TOP1 overlapping the trench TR of the mask frame substrate 253 may be formed in the first portion 2541 of the temporary layer 254. In an embodiment, a portion (e.g., of the first portion 2541) of the temporary layer 254 arranged in the trench TR of the mask frame substrate 253 may be removed during a process of forming the first temporary opening TOP1. In an embodiment, the first temporary opening TOP1 may be formed as a closed-loop or frame shape similar to the trench TR. In an embodiment, a plurality of second temporary openings TOP2 may be formed in the first portion 2541 of the temporary layer 254. In an embodiment, the plurality of second temporary openings TOP2 may be arranged in the first temporary opening TOP1 (or the trench TR) formed as a closed-loop or frame shape in a plan view. In an embodiment, the first temporary opening TOP1 and the plurality of second temporary openings TOP2 may be formed substantially simultaneously. In an embodiment, the first temporary opening TOP1 and the plurality of second temporary openings TOP2 may penetrate the temporary layer 254 (e.g., the first portion 2541 of the temporary layer 254). In an embodiment, the trench TR of the mask frame substrate 253 may be exposed through the first temporary opening TOP1. In an embodiment, a portion of the first surface 2531 of the mask frame substrate 253 that overlaps the plurality of second temporary openings TOP2 may be exposed through the plurality of second temporary openings TOP2.

Referring to FIG. 8G, the mask membrane 252 may be arranged on the mask frame substrate 253 (e.g., on the first surface 2531). The trench TR of the mask frame substrate 253 may be filled by the mask membrane 252. In an embodiment, the first temporary opening TOP1 and the plurality of second temporary openings TOP2 of the temporary layer 254 may be filled by the mask membrane 252. In an embodiment, a portion of the mask membrane 252 may protrude beyond an upper surface of the temporary layer 254, e.g., outside the first temporary opening TOP1 and outside the plurality of second temporary openings TOP2. In an embodiment, the mask membrane 252 may include a metal, and a process of arranging the mask membrane 252 may include a plating process. In an embodiment, the plating process may be appropriately selected according to a material (e.g., a metal) included in the mask membrane 252.

Referring to FIG. 8H, one surface of the mask membrane 252, for example, a surface facing the third direction DR3, may be planarized. In an embodiment, a portion of the mask membrane 252 that protrudes beyond/above the upper surface of the temporary layer 254 may be removed. In an embodiment, a portion of the mask membrane 252 that protrudes outside the first temporary opening TOP1 and outside the plurality of second temporary openings TOP2 may be removed. In an embodiment, a process of removing the portion of the mask membrane 252 may include a chemical mechanical polishing (CMP) process.

Referring to FIGS. 8H and 8I, the mask frame 251 may be formed by etching the mask frame substrate 253. In an embodiment, the mask frame substrate 253 may be etched from the second surface 2532. In an embodiment, before the mask frame substrate 253 is etched from the second surface 2532, the second portion 2542 of the temporary layer 254 may be etched first. In an embodiment, the mask frame substrate 253 may be etched so that the second opening OP2 of the mask frame 251 is formed. In an embodiment, the mask frame substrate 253 may be etched so that a portion of the mask membrane 252 arranged in the trench TR of the mask frame substrate 253 is exposed. In other words, the mask frame substrate 253 may be etched so that a portion (e.g., the protrusion 2521) of the mask membrane 252 protrudes beyond the edge 2513 that defines the second opening OP2 of the mask frame 251. In other words, a portion (e.g., the protrusion 2521) of the mask membrane 252 that is arranged in the trench TR of the mask frame substrate 253 and exposed by the etching of the mask frame substrate 253 may protrude beyond an inner side of the mask frame 251 (e.g., the edge 2513) that defines an opening (e.g., the second opening OP2) formed by the etching of the mask frame substrate 253.

In an embodiment, the mask frame substrate 253 may be etched from the second surface 2532 to the first surface 2531. In other words, a process of etching the mask frame substrate 253 may be performed by penetrating the mask frame substrate 253. In an embodiment, a lower surface (e.g., a surface facing the direction opposite to the third direction DR3) of the first portion 2541 of the temporary layer 254 and a lower surface (e.g., a surface facing the direction opposite to the third direction DR3) of the mask membrane 252 arranged in the plurality of second temporary openings TOP2 of the temporary layer 254 may be exposed. In an embodiment, the third opening OP3 may be formed by removing a portion of the mask frame substrate 253 arranged in the closed-loop (or frame) shape of the trench TR of the mask frame substrate 253 in a plan view. In other words, a space occupied by the portion of the mask frame substrate 253 arranged in the closed-loop (or frame) shape of the trench TR may be emptied (e.g., by etching), and the empty space formed thereby may be defined as the third opening OP3. Because a portion of the mask membrane 252 is arranged in the trench TR of the mask frame substrate 253, the third opening OP3 may be defined by the mask membrane 252 (e.g., the protrusion 2521 of the mask membrane 252). As the third opening OP3 is formed, the trench TR of the mask frame substrate 253 may no longer have the closed-loop (or frame) shape but may have a single hole shape, and this hole may be defined as the first opening OP1 of the mask frame 251.

Referring to FIGS. 8I and 8J, the temporary layer 254 may be removed. In an embodiment, the first portion 2541 and the second portion 2542 of the temporary layer 254 may be removed. A process of removing the temporary layer 254 may include an etching process. In an embodiment, an empty space from which a portion of the temporary layer 254 that defines the plurality of second temporary openings TOP2 is removed may be defined as the plurality of fourth openings OP4. In an embodiment, because a portion of the mask membrane 252 is arranged in the plurality of second temporary openings TOP2, the plurality of fourth openings OP4 may be defined by the mask membrane 252.

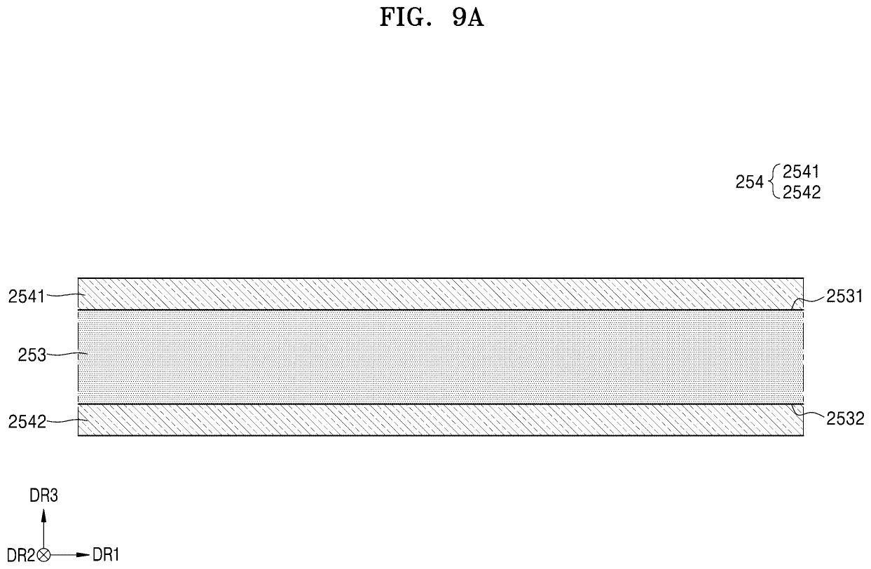

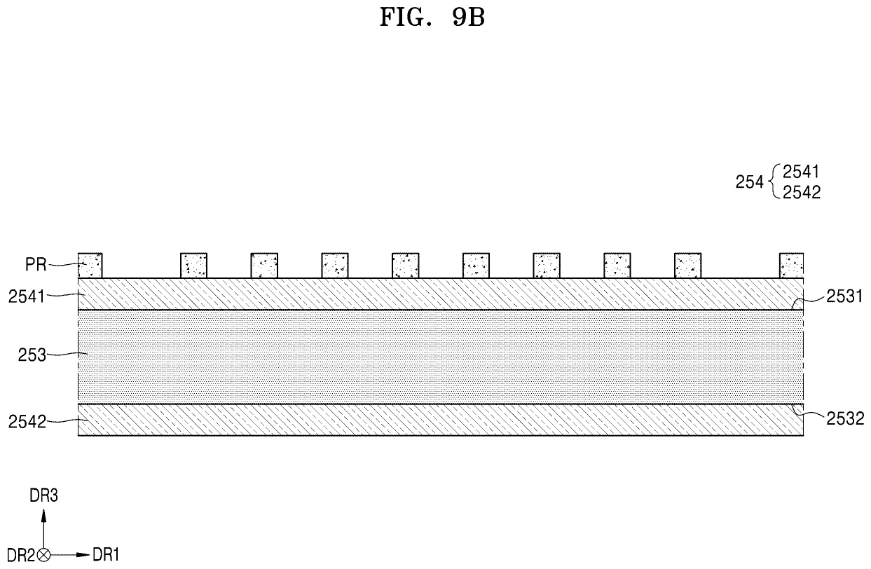

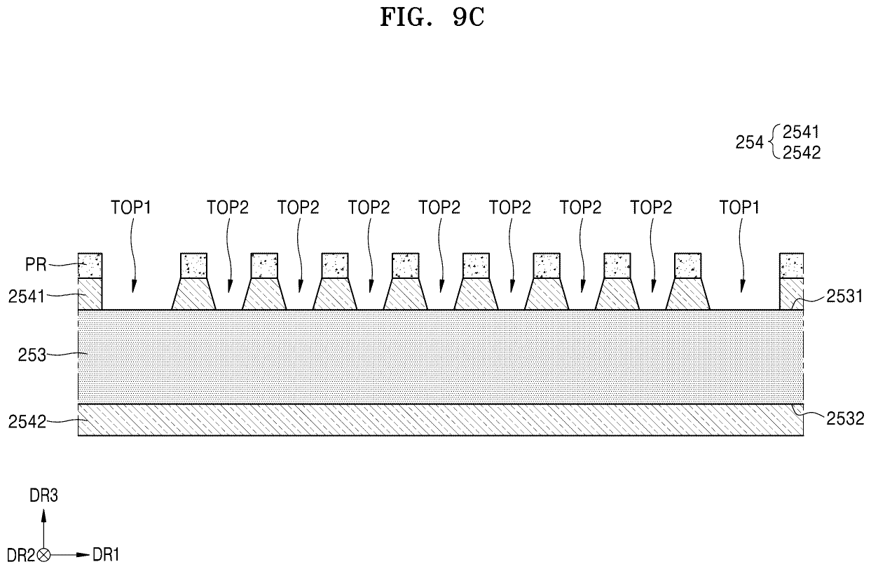

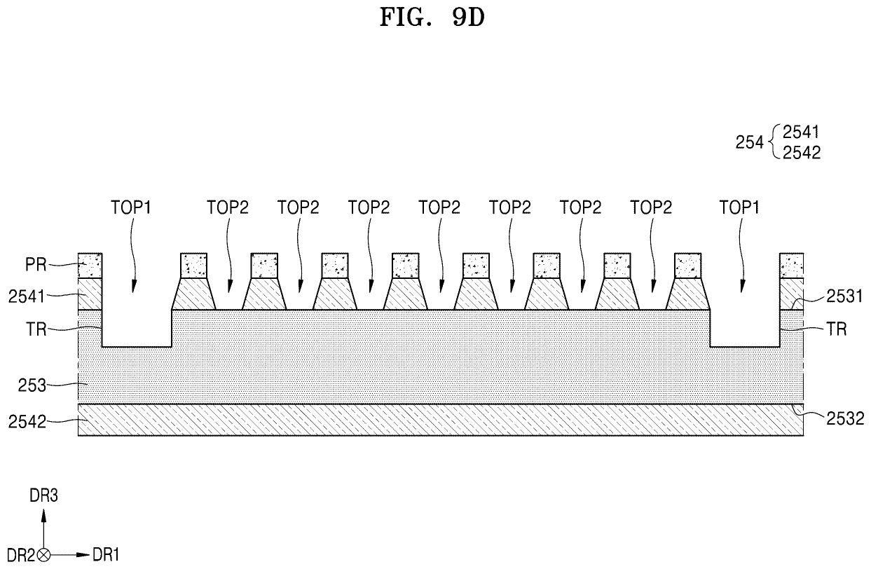

FIGS. 9A, 9B, 9C, and 9D are schematic cross-sectional views illustrating processes of a method of manufacturing a deposition mask, according to an embodiment.

Prior to performing the process shown in FIG. 9A, the mask frame substrate 253 including the first surface 2531 and the second surface 2532 may be prepared, as in the process shown in FIG. 8A.

Referring to FIGS. 9A to 9D in comparison with FIGS. 8B to 8E, a process of arranging the temporary layer 254 may be performed prior to a process of forming the trench TR in the mask frame substrate 253.

FIGS. 9A and 9B illustrate an embodiment in which the temporary layer 254 is arranged on the mask frame substrate 253 in which the trench TR (see FIG. 8C) is not formed. The first portion 2541 of the temporary layer 254 may be arranged on the first surface 2531 of the mask frame substrate 253, and the second portion 2542 of the temporary layer 254 may be arranged on the second surface 2532 of the mask frame substrate 253. The photoresist PR may be arranged on the first portion 2541 of the temporary layer 254.

Referring to FIG. 9C, the first temporary opening TOP1 and the plurality of second temporary openings TOP2 may be formed by etching the first portion 2541 of the temporary layer 254. At the current stage of the process, the first surface 2531 of the mask frame substrate 253 that overlaps the first temporary opening TOP1 may be exposed, but the trench TR may not yet be formed (see FIG. 8E).

Referring to FIG. 9D, the trench TR overlapping the first temporary opening TOP1 may be formed in the mask frame substrate 253. In an embodiment, a process of forming the trench TR may include a process of etching the mask frame substrate 253. In an embodiment, a process of forming the first temporary opening TOP1 in the temporary layer 254 may be performed prior to the process of forming the trench TR in the mask frame substrate 253. In an embodiment, the process of forming the first temporary opening TOP1 in the temporary layer 254 and the process of forming the trench TR in the mask frame substrate 253 may be performed substantially simultaneously.

In the embodiment shown in FIGS. 9A to 9D, before the trench TR is formed in the mask frame substrate 253, the temporary layer 254 is arranged and the first temporary opening TOP1 is formed. Accordingly, because a portion of the temporary layer 254 may not be arranged in the trench TR, a process of removing the portion of the temporary layer 254 arranged in the trench TR may not occur.

In an embodiment, after the process shown in FIG. 9D is performed, the processes shown in FIGS. 8G to 8J may be performed.

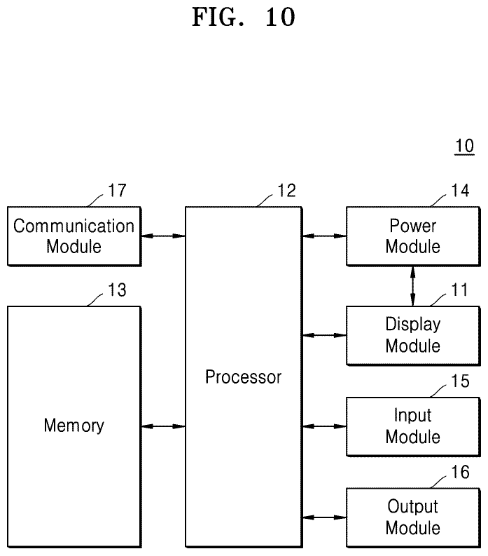

FIG. 10 is a block diagram of an electronic apparatus 10 according to an embodiment.

Referring to FIG. 10, the electronic apparatus 10 may include a display panel 11, a processor 12, a memory 13, and a power module 14. In an embodiment, the display panel 11 may be manufactured by using the apparatus 2 described above with reference to FIGS. 1A and 1B.

The processor 12 may include at least one of a central processing unit (CPU), an application processor (AP), a graphics processing unit (GPU), a communication processor (CP), and an image signal processor (ISP). In an embodiment, the processor 12 may be provided by being divided into two or more processors from a functional or structural point of view. For example, the processor 12 may include a main processor in the form of a first driving chip including a CPU, and an auxiliary processor in the form of a second driving chip including a controller configured to receive an image signal from the main processor and process the image signal to match interface specifications of the display panel 11.

The memory 13 may include at least one of a nonvolatile memory and a volatile memory. The memory 13 may store data information required for the operation of the processor 12 or the display panel 11. When the processor 12 executes an application stored in the memory 13, an image data signal and/or an input control signal may be transmitted to the display panel 11, and the display panel 11 may output image information through a display screen by processing the received signal.

The power module 14 may include a power supply module, such as a power adapter or a battery apparatus, and a power conversion module configured to generate power required for the operation of the electronic apparatus 10 by converting power supplied by the power supply module. Power conversion performed by the power conversion module may include direct current (DC)-DC conversion, alternating current (AC)-DC conversion, and DC-AC conversion, but is not limited thereto.

The electronic apparatus 10 may include an input module 15, a non-image output module 16, and/or a communication module 17.

The input module 15 may provide input information to the processor 12 and/or the display panel 11. The input module 15 may include a physical button, a keyboard, and a microphone, as well as various sensor modules. Examples of sensor modules may include a touch sensor, a pressure sensor, a distance sensor, a position sensor, a digitizer, a motion recognition sensor, a camera sensor, a light-receiving sensor, a photoelectric conversion sensor, a temperature sensor, as well as biosensors, such as a blood pressure sensor, a blood sugar sensor, an electrocardiogram sensor, and a heart rate sensor.

The non-image output module 16 may receive information other than images received from the processor 12 and provide the information to a user. Examples of the non-image output module 16 may include an audio module, a haptic module, and a light-emitting module and may also include other electronic apparatus-specific functional modules (e.g., a cooling module of a refrigerator, etc.).

The communication module 17 is a module configured to transmit and receive information between the electronic apparatus 10 and an external apparatus and may include a receiver and a transmitter. The communication module 17 may include various wireless communication modules, such as a mobile communication module, a wireless-fidelity (Wi-Fi) module, and a Bluetooth module, or various wired communication modules.

At least one of the aforementioned components of the electronic apparatus 10 may be included in a display apparatus. Also, some of individual modules functionally included in a single module may be included in the display apparatus, and others thereof may be provided separately from the display apparatus. For example, the display apparatus may include the display panel 11, and the processor 12, the memory 13, and the power module 14 may be provided in the form of other apparatuses in the electronic apparatus 10 other than the display apparatus. As another example, the power module 14 may be provided in the display apparatus and supply power to the processor 12 and the memory 13 provided in the electronic apparatus 10 other than the display apparatus, and one or more embodiments are not limited to the above examples.

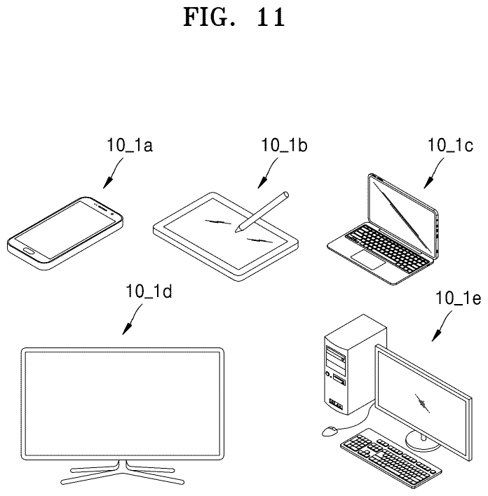

FIGS. 11 to 13 are schematic diagrams of an electronic apparatus according to various embodiments. FIGS. 11 to 13 illustrate examples of various electronic apparatuses to which a display apparatus is applied, according to embodiments.

FIG. 11 illustrates, as examples of the electronic apparatus 10, a smartphone 10_1a, a table personal computer (PC) 10_1b, a laptop computer 10_1c, a television (TV) 10_1d, and a desk monitor 10_1e.

The smartphone 10_1a may include an input module, such as a touch sensor, and a communication module in addition to a display panel. The smartphone 10_1a may process information received via the communication module or another input module and display the information via the display panel of the display apparatus.

Similar to the smartphone 10_1a, the tablet PC 10_b, the laptop computer 10_1c, the TV 10_d, and the desk monitor 10_1e may each include a display panel and an input module, and in some cases, may further include a communication module.

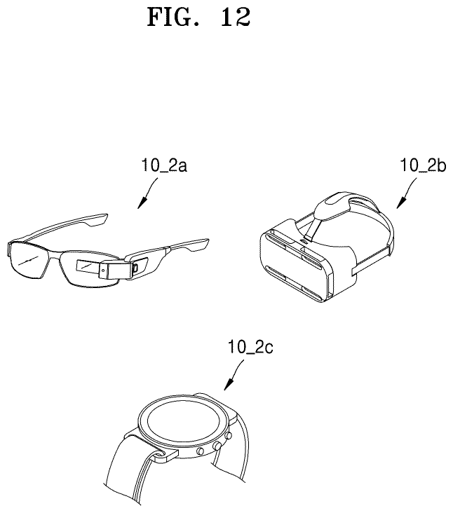

FIG. 12 illustrates a case where an electronic apparatus including a display panel is applied to a wearable electronic apparatus. The wearable electronic apparatus may include smart glasses 10_2a, a head-mount display 10_2b, and a smart watch 10_2c.

The smart glasses 10_2a and the head-mount display 10_2b may each include a display panel configured to project a display image and a reflector configured to reflect the projected display image and provide the same to a user's eyes, thereby providing a virtual reality or augmented reality screen to the user.

The smart watch 10_2c may include a biometric sensor as an input apparatus and may provide biometric information identified by the biometric sensor to the user via the display panel.

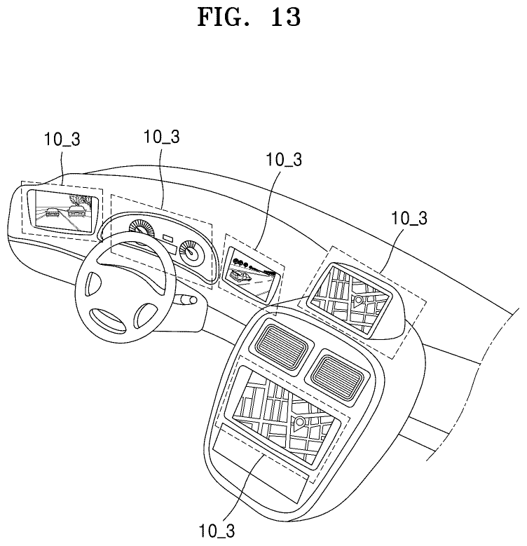

FIG. 13 illustrates a case where an electronic apparatus 10_3 including a display panel is applied to a vehicle. For example, the electronic apparatus 10_3 may be applied to an instrument panel or a center fascia of a vehicle or may be applied to a central information display (CID) arranged on a dashboard of a vehicle, or a room mirror display functioning in place of a side mirror of a vehicle.

Although not shown, an electronic apparatus to which the display apparatus according to embodiments may include not only apparatuses that mainly display screens, such as a billboard, an electronic board, and a game console, but also various home appliances that display information through display panels, such as a refrigerator, a washing machine, a drying machine, an air conditioner, and a robot vacuum cleaner. Also, when a display panel has a function of transmitting light, the display panel may be applied to an electronic apparatus, such as a smart window or a transparent display apparatus that displays a background and a displayed image together. The types of electronic apparatuses according to an embodiment are not limited to those illustrated above, and the application of various other electronic apparatuses not illustrated may also be possible.

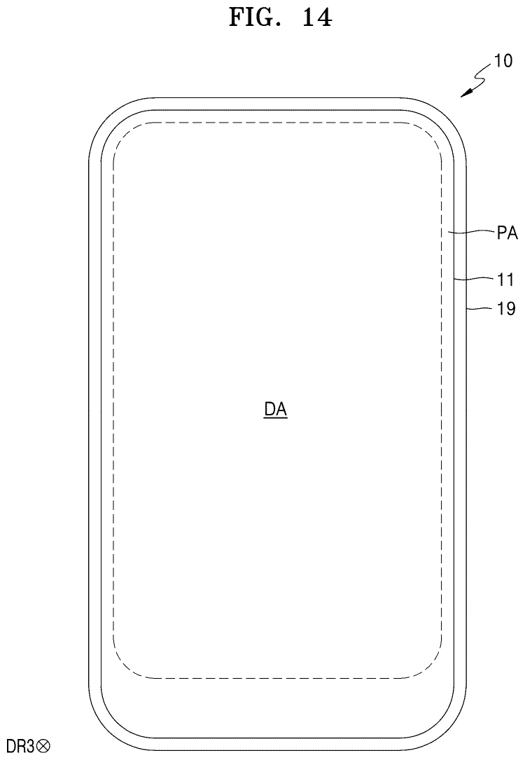

FIG. 14 is a schematic plan view of the electronic apparatus 10 according to an embodiment. FIG. 15 is a cross-sectional view of the display panel 11 according to an embodiment.

FIG. 14 illustrates an embodiment in which the electronic apparatus 10 is a smartphone, but one or more embodiments are not limited thereto. The electronic apparatus 10 may include the display panel 11 and a housing 19. In an embodiment, the display panel 11 may be accommodated in the housing 19. The housing 19 may not be necessarily implemented in the form shown in FIG. 14, and may be of any form or shape as long as the housing 19 provides a space to accommodate the display panel 11.

Referring to FIGS. 14 and 15, a display area DA and a peripheral area PA outside the display area DA may be defined on a substrate 91 of the display panel 11. A light-emitting element 98 may be arranged in the display area DA, and a power line (not shown) may be arranged in a non-display area.

A plurality of deposition material patterns may be arranged in the display area DA. FIG. 14 illustrates that the display panel 11 and the display area DA have a substantially quadrangular shape, but one or more embodiments are not limited thereto. The display panel 11 and/or the display area DA may also have other shapes, for example, an irregular shape.

The display panel 11 may include the substrate 91, a thin-film transistor TFT arranged on the substrate 91, and the light-emitting element 98 arranged on the thin-film transistor TFT. The light-emitting element 98 may be electrically connected to the thin-film transistor TFT.

The substrate 91 may include a plastic material or may include a metal material. In an embodiment, the substrate 91 may include polyimide (PI). The thin-film transistor TFT may be arranged over the substrate 91, a via-layer 97 may be arranged to cover the thin-film transistor TFT, and the light-emitting element 98 may be arranged on the via-layer 97.

A buffer layer 92 including an inorganic insulating material may be further arranged on an upper surface of the substrate 91. The buffer layer 92 may include SiO₂, silicon nitride (SiNₓ), and/or silicon oxynitride (SiON).

An active layer 93 may be arranged in a certain pattern on the buffer layer 92, and the active layer 93 may be covered by a gate insulating layer 94. The active layer 93 may include a source region 93-1 and a drain region 93-3, and a channel region 93-2 between the source region 93-1 and the drain region 93-3.

The active layer 93 may be formed to include various materials. In an embodiment, the active layer 93 may include an inorganic semiconductor material, such as amorphous silicon or crystalline silicon. In an embodiment, the active layer 93 may include an oxide semiconductor. In an embodiment, the active layer 93 may include an organic semiconductor material.

The active layer 93 may be formed by forming an amorphous silicon film on the buffer layer 92, crystallizing the amorphous silicon film to form a polycrystalline silicon film, and then patterning the polycrystalline silicon film. The source region 93-1 and the drain region 93-3 of the active layer 93 may be doped with impurities.

A gate electrode 95 corresponding to the active layer 93 and an interlayer insulating layer 96 covering the gate electrode 95 may be arranged on an upper surface of the gate insulating layer 94. After a contact hole H1 is formed in the interlayer insulating layer 96 and the gate insulating layer 94, a source electrode 97-1 and a drain electrode 97-2 may be arranged on the interlayer insulating layer 96 to be in contact with the source region 93-1 and the drain region 93-3, respectively.

The via-layer 97 may be arranged on the thin-film transistor TFT, and a pixel electrode 98-1 of the light-emitting element 98 may be arranged on the via-layer 97. The pixel electrode 98-1 may be in contact with the drain electrode 97-2 of the thin-film transistor TFT through a via hole H2 formed in the via-layer 97. The via-layer 97 may include an inorganic material and/or an organic material, may include a single layer or two mor more layers, and may be formed as a planarization layer so that the upper surface is flat regardless of the curvature of a lower layer, or may be formed to have a curvature along the curvature of the lower layer.

After the pixel electrode 98-1 is arranged on the via-layer 97, a pixel-defining layer 99 may be formed to cover the pixel electrode 98-1 and the via-layer 97, and the pixel-defining layer 99 may be open so that a portion of the pixel electrode 98-1 is exposed.

An intermediate layer 98-2 and an opposite electrode 98-3 may be arranged over the pixel electrode 98-1. The opposite electrode 98-3 may be arranged on the intermediate layer 98-2 and the pixel-defining layer 99. In an embodiment, the opposite electrode 98-3 may be arranged on the front surface of the substrate 91.

The intermediate layer 98-2 may include an emission layer. In an embodiment, the intermediate layer 98-2 may include an emission layer and may further include at least one of a hole injection layer, a hole transport layer, an electron transport layer, and an electron injection layer. One or more embodiments are not limited thereto, and the intermediate layer 98-2 may include an emission layer and may further include various other functional layers (not shown).

The pixel electrode 98-1 and the opposite electrode 98-3 may be insulated from each other by the intermediate layer 98-2. Voltages of different polarities are applied to the intermediate layer 98-2 by the pixel electrode 98-1 and the opposite electrode 98-3 such that light emission may occur in the emission layer included in the intermediate layer 98-2.

A plurality of intermediate layers 98-2 may be provided, and the plurality of intermediate layers 98-2 may form the display area DA. In this case, the plurality of intermediate layers 98-2 may be arranged to be spaced apart from each other inside the display area DA. In an embodiment, a pattern in which the plurality of intermediate layers 98-2 are arranged may be determined by the deposition area of the deposition mask 25 (see FIG. 1A) described above.

A thin-film encapsulation layer E may include a plurality of inorganic layers or may include an inorganic layer and an organic layer. The organic layer of the thin-film encapsulation layer E may include a polymer and may include a single layer or a laminated layer including any one of polyethylene terephthalate, PI, polycarbonate, epoxy, polyethylene, and polyacrylate. The inorganic layer of the thin-film encapsulation layer E may include a single layer or a laminated layer including metal oxide or metal nitride. For example, the inorganic layer may include any one of SiO₂, SiNₓ, SiON, aluminum oxide (Al₂O₃), and titanium oxide (TiO₂). The uppermost layer of the thin-film encapsulation layer E exposed to the outside may include an inorganic layer to prevent moisture penetration into the light-emitting element 98.

The thin-film encapsulation layer E may include at least one sandwich structure in which at least one organic layer is inserted between at least two inorganic layers. As another example, the thin-film encapsulation layer E may include at least one sandwich structure in which at least one inorganic layer is inserted between at least two organic layers. As another example, the thin-film encapsulation layer E may include a sandwich structure in which at least one organic layer is inserted between at least two inorganic layers and a sandwich structure in which at least one inorganic layer is inserted between at least two organic layers.

As described above, the one or more embodiments have been described with reference to the accompanying drawings, but the embodiments should be considered in a descriptive sense only. Those of ordinary skill in the art will understand that various modifications and changes to the embodiments may be made therefrom. Therefore, the true technical scope of protection of the disclosure should be defined by the technical spirit of the appended claims.

According to the one or more embodiments as described above, a deposition mask including a mask membrane, of which a portion protrudes to overlap an opening of a mask frame, is provided. This may prevent (or at least reduce) damage to the mask membrane caused by corners of the mask frame colliding with the mask membrane. According to an embodiment, a method of manufacturing the deposition mask having the aforementioned structure is provided. According to an embodiment, an apparatus for manufacturing a display panel, the apparatus including the deposition mask having the aforementioned structure, is provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A deposition mask comprising:
a mask frame including a first surface and a second surface opposite to the first surface, wherein a first opening is defined in the mask frame to be open toward the first surface, and a second opening is defined in the mask frame to be open toward the second surface; and
a mask membrane of which at least a portion is arranged in the first opening of the mask frame, the mask membrane including a protrusion protruding beyond an inner edge of the mask frame defining the second opening and protruding inside.

2. The deposition mask of claim 1, wherein a size of the first opening is greater than or equal to a size of the second opening.

3. The deposition mask of claim 1, wherein the first opening and the second opening communicate to each other and penetrate the mask frame together.

4. The deposition mask of claim 1, wherein an inner side of the mask frame defining the second opening is tapered such that a size of the second opening changes in a direction toward the first opening.

5. The deposition mask of claim 1, wherein the protrusion has a round edge.

6. The deposition mask of claim 1, wherein a portion of the mask membrane protrudes beyond the first surface of the mask frame and protrudes upward.

7. The deposition mask of claim 1, wherein the mask membrane includes:
a third opening defined by the protrusion and overlapping the first opening and the second opening of the mask frame in a plan view; and
a plurality of fourth openings overlapping the first opening, the second opening, and the third opening, the plurality of fourth openings defining a deposition area.

8. The deposition mask of claim 7, wherein a portion of the mask membrane defining the third opening therein is arranged in the first opening, and another portion of the mask membrane defining the plurality of fourth openings therein is arranged above and protrudes from the first surface of the mask frame.

9. A method of manufacturing a deposition mask, the method comprising:
forming a trench in a first surface of a mask frame substrate;
arranging a mask membrane on the first surface of the mask frame substrate to fill the trench of the mask frame substrate; and
etching the mask frame substrate from a second surface thereof such that a portion of the mask membrane arranged in the trench is exposed, the second surface being opposite to the first surface.

10. The method of claim 9, further comprising: before the arranging of the mask membrane, arranging a temporary layer on an outer surface of the mask frame substrate to cover the first surface and the second surface of the mask frame substrate.

11. The method of claim 10, further comprising forming a first temporary opening in a first portion of the temporary layer arranged on the first surface of the mask frame substrate, the first temporary opening overlapping the trench of the mask frame substrate in a plan view.

12. The method of claim 11, wherein, during the arranging of the temporary layer, the trench of the mask frame substrate is filled with the first portion of the temporary layer, and during the forming of the first temporary opening, a portion of the temporary layer arranged in the trench is removed.

13. The method of claim 11, wherein the arranging of the temporary layer is performed prior to the forming of the trench of the mask frame substrate, and the forming of the first temporary opening of the temporary layer is performed simultaneously with or prior to the forming of the trench of the mask frame substrate.

14. The method of claim 11, wherein the trench of the mask frame substrate and the first temporary opening of the temporary layer are each formed as a closed-loop in the plan view, and
the method further comprises forming a plurality of second temporary openings in the first portion of the temporary layer, the plurality of second temporary openings being arranged in the closed-loop in the plan view.

15. The method of claim 14, wherein, in the arranging of the mask membrane, the trench of the mask frame substrate and the first temporary opening and the plurality of second temporary openings of the temporary layer are filled by the mask membrane.

16. The method of claim 15, further comprising removing a portion of the mask membrane protruding outside the first temporary opening or outside the plurality of second temporary openings.

17. The method of claim 10, further comprising removing the temporary layer.

18. The method of claim 9, wherein, in the etching of the mask frame substrate from the second surface, the etching is performed to penetrate the mask frame substrate from the second surface to the first surface.

19. The method of claim 9, wherein a portion of the mask membrane arranged in the trench and exposed by the etching of the mask frame substrate protrudes beyond an inner edge of the mask frame defining an opening formed by the etching of the mask frame substrate.

20. An apparatus for manufacturing a display panel, the apparatus comprising:
a chamber;
a deposition mask arranged in the chamber; and
a deposition source arranged to face the deposition mask in the chamber,
wherein the deposition mask includes:
a mask frame including a first surface and a second surface opposite to the first surface, wherein a first opening is defined in the mask frame to be open toward the first surface, and a second opening is defined in the mask frame to be open toward the second surface; and
a mask membrane of which at least a portion is arranged in the second opening of the mask frame, the mask membrane including a protrusion protruding beyond an inner edge of the mask frame defining the first opening and protruding inside.
